(19) United States
(12) Patent Application Publication
(10) Pub. No.: US 2026/0164778 A1
(43) Pub. Date: Jun. 11, 2026

(54) SEMICONDUCTOR DEVICE AND METHOD OF MANUFACTURING THE SAME

(71) Applicant: Renesas Electronics Corporation, Tokyo (JP)

(72) Inventor: Komaki INOUE, Tokyo (JP)

(21) Appl. No.: 19/368,179

(22) Filed: Oct. 24, 2025

(30) Foreign Application Priority Data
Dec. 11, 2024 (JP) 2024-217059

(51) Int. Cl. H10D 84/83; H10D 30/01; H10D 30/65; H10D 62/10; H10D 62/60; H10D 84/01

(52) U.S. Cl. CPC H10D 84/835; H10D 30/0281; H10D 30/65; H10D 62/102; H10D 62/116; H10D 62/124; H10D 62/60; H10D 84/0163; H10D 84/8312

(57) ABSTRACT

A semiconductor device includes an n-type offset drain region, an n-type semiconductor region, and a gate electrode. The n-type semiconductor region is arranged apart from the n-type offset drain region.

### CROSS-REFERENCE TO RELATED APPLICATIONS

The disclosure of Japanese Patent Application No. 2024-217059 filed on Dec. 11, 2024 including the specification, drawings and abstract is incorporated herein by reference in its entirety.

### BACKGROUND

The present invention relates to a semiconductor device and a manufacturing technique of the same, and relates to a technique effective when applied to, for example, a semiconductor device including a plurality of metal oxide semiconductor field effect transistors (MOSFETs) having different threshold voltages from one another and a manufacturing technique thereof.

There are disclosed techniques listed below. [Patent Document 1] Japanese Unexamined Patent Application Publication No. 2020-129597

Patent Document 1 discloses a technique related to a laterally diffused metal oxide semiconductor field effect transistor (referred to as LDMOSFET).

### SUMMARY

For example, as an LDMOSFET used in a circuit, not only an enhancement-type LDMOSFET and a depletion-type LDMOSFET but also an enhancement-type low-Vth LDMOSFET having a relatively low threshold voltage is required.

Accordingly, a semiconductor device including not only the enhancement-type LDMOSFET and the depletion-type LDMOSFET but also the low-Vth LDMOSFET has been examined.

In this regard, in order to simplify the manufacturing process of the low-Vth LDMOSFET and reduce the manufacturing cost of the semiconductor device, ingenuity concerning the structure of the low-Vth LDMOSFET and the manufacturing process of the semiconductor device are desired.

Other objects and novel features will become apparent from the description of the present specification and the accompanying drawings.

According to an embodiment, a semiconductor device includes an epitaxial layer of a first conductivity type, a first well formed in the epitaxial layer, the first well being of the first conductivity type, a first offset drain region formed in the epitaxial layer and arranged apart from the first well, the first offset drain region being of a second conductivity type, a first source region formed in the first well, the first source region being of the second conductivity type, a first semiconductor region formed in the first well, in contact with the first source region, arranged apart from the first offset drain region, and having an impurity concentration lower than an impurity concentration of the first source region, the semiconductor region being of the second conductivity type, and a first gate electrode formed on each of: a portion of the first offset drain region, a portion, which is located between the first offset drain region and the first semiconductor region, of the epitaxial layer, and the first semiconductor region, via a first gate insulating film. Here, in a gate length direction of the first gate electrode, a length of the portion, which is located between the first offset drain region and the first semiconductor region, of the epitaxial layer is equal to or less than a length of the first semiconductor region.

According to an embodiment, a method of manufacturing a semiconductor device includes steps of (a) forming an epitaxial layer of a first conductivity type, the epitaxial layer having a first portion and a second portion, (b) by implanting an impurity into the epitaxial layer, forming a first well in the first portion, and forming a second well in the second portion, each of the first well and the second well being of the first conductivity type, (c) forming a first offset drain region in the first portion at a position spaced apart from the first well, the first offset drain region being of a second conductivity type, (d) forming a second offset drain region in the second portion at a position spaced apart from the second well, the second offset drain region being of the second conductivity type, (e) forming a mask covering the first offset drain region, a portion, which is in contact with the first offset drain region, of the first portion of the epitaxial layer, and a portion of the second offset drain region, while exposing, at least a portion of the first well, an other portion of the second offset drain region, a portion, which is located between the second offset drain region and the second well, of the epitaxial layer, and the second well, on the epitaxial layer, and (f) by introducing an impurity of the second conductivity type into the epitaxial layer in a state in which the mask is formed, forming a first semiconductor region in the first well, and forming a second semiconductor region in each of the second well and the portion, which is located between the second offset drain region and the second well, of the epitaxial layer.

According to one embodiment, a manufacturing process of a semiconductor device including a low-Vth LDMOSFET can be simplified, and a manufacturing cost of the semiconductor device can be reduced.

### BRIEF DESCRIPTION OF THE DRAWINGS

FIG. 1 is a cross-sectional view illustrating a configuration formed in a region 1A of a semiconductor device.

FIG. 2 is a cross-sectional view illustrating a structure formed in a region 1B of the semiconductor device.

FIG. 3 is a diagram illustrating a configuration of a channel formation region located between an n-type offset drain region and a source region.

FIG. 4 is a graph (1) illustrating a relationship between a position of a mask edge and a threshold voltage Vth, a graph (2) illustrating a relationship between D of the mask edge and a length LA, and a graph (3) illustrating a relationship between the position of the mask edge and a length LB.

FIG. 5 is a diagram illustrating a manufacturing process of a semiconductor device according to an embodiment.

FIG. 6 is a diagram illustrating a manufacturing process of the semiconductor device following FIG. 5.

FIG. 7 is a diagram illustrating a manufacturing process of the semiconductor device following FIG. 6.

FIG. 8 is a diagram illustrating a manufacturing process of the semiconductor device following FIG. 7.

FIG. 9 is a diagram illustrating a manufacturing process of the semiconductor device following FIG. 8.

FIG. 10 is a diagram illustrating a manufacturing process of the semiconductor device following FIG. 9.

FIG. 11 is a diagram illustrating a manufacturing process of the semiconductor device following FIG. 10.

FIG. 12 is a diagram illustrating a manufacturing process of the semiconductor device following FIG. 11.

### DETAILED DESCRIPTION

In all the drawings for describing the embodiment, the same reference numerals are basically assigned to the same components, and repeated explanations thereof are omitted. It should be noted that, for ease of understanding the drawings, hatching may be applied even in plan views.

It should also be noted that in the present specification, for example, it is described that impurity concentrations or lengths of two configurations are the same (similar) to each other. However, such a description does not intend to mean that the impurity concentrations or lengths are exactly identical. In practice, manufacturing variations are present. Accordingly, the term “the same” in the present specification also includes cases where differences within the range of manufacturing variations are present.

As a LDMOSFET, a depletion-type LDMOSFET and an enhancement-type LDMOSFET are known. The LDMOSFET includes a p-channel type LDMOSFET and an n-channel type LDMOSFET. The technical concept of the present disclosure is applicable to both the p-channel type LDMOSFET and the n-channel type LDMOSFET. However, in the present specification, the description will be made assuming an n-channel LDMOSFET.

When the depletion-type LDMOSFET is the n-channel type LDMOSFET, the depletion-type LDMOSFET has a negative threshold voltage. On the other hand, when the enhancement-type LDMOSFET is the n-channel type LDMOSFET, the enhancement-type LDMOSFET has a positive threshold voltage.

The depletion-type LDMOSFET is also referred to as a normally-on type LDMOSFET. Also, the enhancement-type LDMOSFET is also referred to as a normally-off type LDMOSFET. In the present specification, the enhancement-type LDMOSFET includes two types of LDMOSFETs having different threshold voltages from each other. Of the two types, the LDMOSFET having a relatively high threshold voltage is simply referred to as the LDMOSFET in some cases. On the other hand, the LDMOSFET having a relatively low threshold voltage of the two types is referred to as a low-Vth LDMOSFET.

For example, the depletion-type LDMOSFET has been examined for use in a constant current source. This is because when the depletion-type LDMOSFET is used in the constant current source, power consumption of the semiconductor device can be reduced. Therefore, there is a need for using the depletion-type LDMOSFET in the constant current source. In contrast, the low-Vth LDMOSFET has been examined for use in a sense circuit. This is because, by using the low-Vth LDMOSFET in the sense circuit, stability of the sense circuit can be improved. In addition, when the low-Vth LDMOSFET is used in the sense circuit, a capacitor provided in the sense circuit becomes unnecessary, and as a result, chip size can be reduced. Therefore, there is a need for using the low-Vth LDMOSFET in the sense circuit.

From the above, a semiconductor device including not only an LDMOSFET but also a low-Vth LDMOSFET and a depletion-type LDMOSFET has been examined. In this regard, there is room for improvement in the semiconductor device. The room for the improvement will be described below.

### Room for Improvement

Adjustment of a threshold voltage of a MOSFET can be realized by adjusting the work function of a gate electrode material and a gate insulating film capacitance per unit area. However, in general, adjustment of the threshold voltage of the MOSFET is often performed by adjusting an impurity concentration of a well and an upper surface region of the well, without adjusting the work function of the gate electrode material and the gate insulating film capacitance per unit area. This is because the impurity concentration of the well and the upper surface region of the well can be easily adjusted by an ion implantation amount of an impurity.

For example, an impurity concentration of the well of the LDMOSFET is similar to an impurity concentration of the well of the depletion-type LDMOSFET. In addition, an impurity concentration of an upper surface region of the well of the LDMOSFET is similar to an impurity concentration of the upper surface region of the well of the depletion-type LDMOSFET. However, in the depletion-type LDMOSFET, an n-type semiconductor region is formed so as to reach an offset drain region via an upper surface of an epitaxial layer from the upper surface region of the well. As a result, in the depletion-type LDMOSFET having the n-type semiconductor region, a negative threshold voltage is realized. In contrast, in the LDMOSFET not having the n-type semiconductor region, a positive threshold voltage is realized.

On the other hand, in the low-Vth LDMOSFET, in order to realize a positive threshold voltage lower than that of the LDMOSFET, an impurity concentration of a well of the low-Vth LDMOSFET is different from the impurity concentration of a well of the LDMOSFET. Similarly, an impurity concentration of an upper surface region of the well of the low-Vth LDMOSFET is different from the impurity concentration of the upper surface region of the well of the LDMOSFET.

Therefore, in order to manufacture the semiconductor device including not only the LDMOSFET but also the low-Vth LDMOSFET and the depletion-type LDMOSFET, it is necessary to additionally provide (1) a mask and an ion implantation step for forming an n-type semiconductor region by an ion implantation method, and (2) a mask and an ion implantation step for forming the well and the upper surface region of the well of the low-Vth LDMOSFET by the ion implantation method, compared with manufacturing the semiconductor device including the LDMOSFET. In this case, manufacturing cost of the semiconductor device increases.

From the above, in order to simplify a manufacturing process of the semiconductor device including not only the LDMOSFET but also the low-Vth LDMOSFET and the depletion-type LDMOSFET, and to reduce the manufacturing cost of the semiconductor device, ingenuity in the structure of the low-Vth LDMOSFET and the manufacturing process of the semiconductor device is desired. In the following, such ingenuity of the present disclosure will be described.

### Basic Concept

An impurity concentration of a well of the low-Vth LDMOSFET is similar to an impurity concentration of a well of the LDMOSFET and the depletion-type LDMOSFET. An impurity concentration of an upper surface region of the well of the low-Vth LDMOSFET is similar to an impurity concentration of an upper surface region of the well of the LDMOSFET and the depletion-type LDMOSFET. The low-Vth LDMOSFET includes an n-type semiconductor region formed in the same step as the n-type semiconductor region formed in the depletion-type LDMOSFET, and a layout of the n-type semiconductor region of the low-Vth LDMOSFET is different from a layout of the n-type semiconductor region of the depletion-type LDMOSFET.

Accordingly, in the LDMOSFET, the low-Vth LDMOSFET, and the depletion-type LDMOSFET, the impurity concentrations of the wells are the same with each other. Similarly, in the LDMOSFET, the low-Vth LDMOSFET, and the depletion-type LDMOSFET, the impurity concentrations of the upper surface regions of the wells are the same with each other. Accordingly, the wells of the LDMOSFET, the low-Vth LDMOSFET, and the depletion-type LDMOSFET can be formed in the same ion implantation step, and the upper surface regions of the wells can also be formed in the same ion implantation step. That is, according to the basic concept, it is unnecessary to additionally provide the ion implantation step for forming the well and the upper surface region of the well specifically for the low-Vth LDMOSFET.

In addition, the n-type semiconductor region of the low-Vth LDMOSFET can be formed in the same ion implantation step as the n-type semiconductor region of the depletion-type LDMOSFET. At this point, the layout of the n-type semiconductor region of the low-Vth LDMOSFET and the layout of the n-type semiconductor region of the depletion-type LDMOSFET can be changed by a mask used in the same ion implantation step.

From the above, according to the basic concept, by ingenuity in the structure of the low-Vth LDMOSFET as described above, the manufacturing process of the semiconductor device including not only the LDMOSFET but also the low-Vth LDMOSFET and the depletion-type LDMOSFET can be simplified. As a result, according to the basic concept, the manufacturing cost of the semiconductor device can be reduced.

In the following, an embodiment implementing the basic concept will be described.

### Embodiment

### <<Configuration of Semiconductor Device>>

A semiconductor device 100 has a region 1A and a region 1B. The semiconductor device 100 includes a p-type semiconductor substrate and a p-type epitaxial layer formed over the region 1A and the region 1B. In the region 1A, a depletion-type LDMOSFET is formed. In contrast, in the region 1B, a low-Vth LDMOSFET is formed.

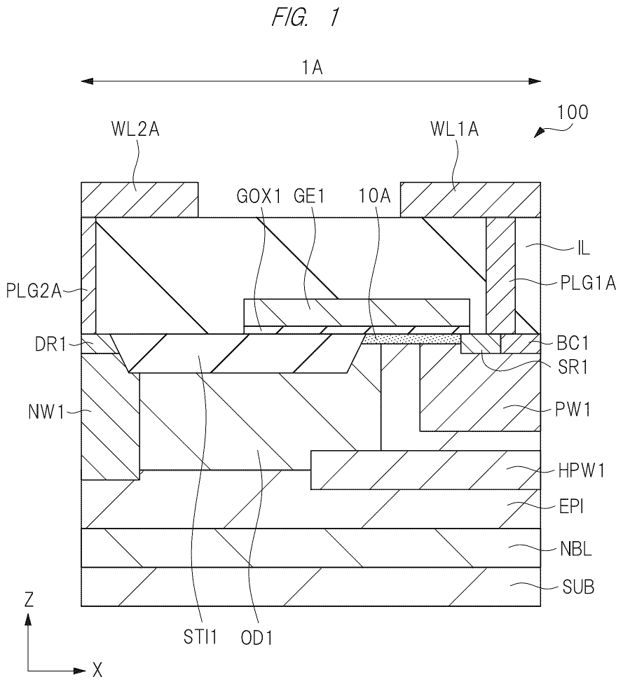

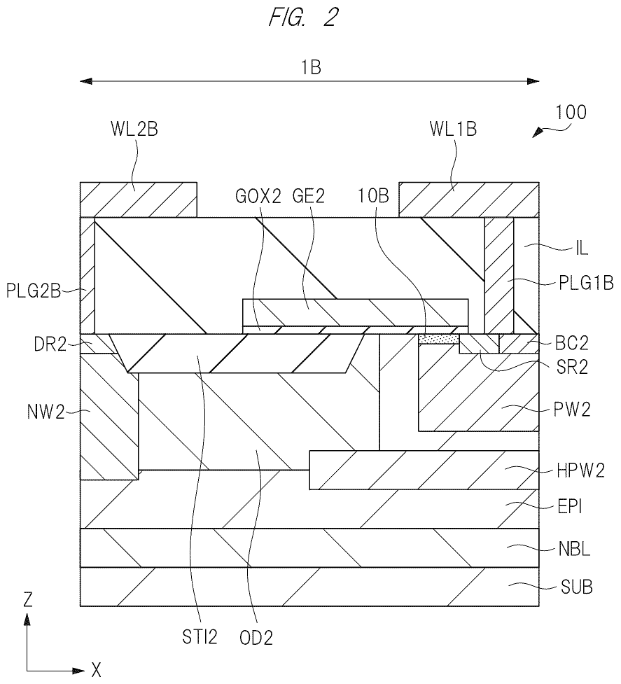

Here, the region 1A illustrated in FIG. 1 described later includes a second portion of the p-type epitaxial layer EPI. The region 1B illustrated in FIG. 2 described later includes a first portion of the p-type epitaxial layer EPI. The depletion-type LDMOSFET is formed in the second portion of the p-type epitaxial layer EPI. Also, the low-Vth LDMOSFET is formed in the first portion of the p-type epitaxial layer EPI.

FIG. 1 is a cross-sectional view illustrating a configuration formed in the region 1A of the semiconductor device 100.

In the region 1A, the depletion-type LDMOSFET is formed.

In FIG. 1, the semiconductor device 100 includes a p-type semiconductor substrate SUB, an n-type buried layer NBL, the p-type epitaxial layer EPI, a p-type RESURF layer HPW1, a p-type well PW1, an n-type well NW1, an n-type offset drain region OD1, an insulating region STI1, a drain region DR1, a source region SR1, a body contact region BC1, an n-type semiconductor region 10A, a gate insulating film GOX1, a gate electrode GE1, an interlayer insulating film IL, a plug PLG1A, a plug PLG2A, a source wiring WL1A, and a drain wiring WL2A.

The n-type buried layer NBL is formed between the p-type semiconductor substrate SUB and the p-type epitaxial layer EPI. The n-type buried layer NBL may be formed in the p-type semiconductor substrate SUB or may be formed in the p-type epitaxial layer EPI.

In the p-type epitaxial layer EPI, the p-type RESURF layer HPW1, the p-type well PW1, the n-type well NW1, the n-type offset drain region OD1, the insulating region STI1, the drain region DR1, the source region SR1, the body contact region BC1, and the n-type semiconductor region 10A are formed.

An impurity concentration of the p-type RESURF layer HPW1 is higher than an impurity concentration of the p-type epitaxial layer EPI. Similarly, an impurity concentration of the p-type well PW1 is higher than the impurity concentration of the p-type epitaxial layer EPI. In addition, an impurity concentration of the n-type offset drain region OD1 is lower than an impurity concentration of the n-type well NW1.

The insulating region STI1 is formed in the n-type offset drain region OD1 and in the n-type well NW1. The insulating region STI1 includes a trench formed on an upper surface of the p-type epitaxial layer EPI and an insulating film buried in the trench. The insulating region STI1 is located between the source region SR1 and the drain region DR1 in an X direction in FIG. 1.

In the n-type well NW1, the drain region DR1 is formed. The drain region DR1 is in contact with the insulating region STI1. The drain region DR1 is an n-type semiconductor region. An impurity concentration of the drain region DR1 is higher than the impurity concentration of the n-type well NW1.

In the p-type well PW1, the source region SR1 and the body contact region BC1 are formed. The source region SR1 and the body contact region BC1 are in contact with each other. The source region SR1 is an n-type semiconductor region. On the other hand, the body contact region BC1 is a p-type semiconductor region. An impurity concentration of the source region SR1 is higher than the impurity concentration of the n-type offset drain region OD1 and is approximately equal to the impurity concentration of the drain region DR1. An impurity concentration of the body contact region BC1 is higher than the impurity concentration of the p-type well PW1.

On the upper surface of the p-type epitaxial layer EPI, the n-type semiconductor region 10A is formed. Specifically, in the X direction of FIG. 1, the n-type semiconductor region 10A is formed in the p-type well PW1, in the n-type offset drain region OD1, and in the p-type epitaxial layer EPI located between the p-type well PW1 and the n-type offset drain region OD1. The n-type semiconductor region 10A is in contact with the source region SR1 and the insulating region STI1. However, the n-type semiconductor region 10A may not be formed in the n-type offset drain region OD1. In this case, the n-type semiconductor region 10A is not in contact with the insulating region STI1 and is in contact with the n-type offset drain region OD1.

On a portion of the insulating region STI1, on the n-type semiconductor region 10A, and on a portion of the source region SR1, the gate electrode GE1 is formed via the gate insulating film GOX1.

Here, the X direction of FIG. 1 is a gate length direction of the gate electrode GE1. Therefore, in the gate length direction of the gate electrode GE1, the n-type semiconductor region 10A is formed in the p-type well PW1, in the n-type offset drain region OD1, and in the p-type epitaxial layer EPI located between the p-type well PW1 and the n-type offset drain region OD1.

On the drain region DR1, on a portion of the insulating region STI1, on the gate electrode GE1, on the source region SR1, and on the body contact region BC1, the interlayer insulating film IL is formed. In the interlayer insulating film IL, the plug PLG1A and the plug PLG2A penetrating the interlayer insulating film IL are formed. The plug PLG1A is connected to the source region SR1 and the body contact region BC1. Therefore, the source region SR1 and the body contact region BC1 are electrically connected to each other via the plug PLG1A. On the other hand, the plug PLG2A is connected to the drain region DR1.

On the interlayer insulating film IL, the source wiring WL1A and the drain wiring WL2A are formed. The source wiring WL1A is connected to the plug PLG1A. Therefore, the source wiring WL1A is electrically connected to the source region SR1 and the body contact region BC1 via the plug PLG1A. The drain wiring WL2A is connected to the plug PLG2A. Therefore, the drain wiring WL2A is electrically connected to the drain region DR1 via the plug PLG2A.

In an enhancement-type LDMOSFET, which is not illustrated, a p-type semiconductor region having an impurity concentration different from that of the p-type well is formed in an upper surface region of the p-type well. This p-type semiconductor region adjusts a threshold voltage for forming a channel and has a function of realizing a positive threshold voltage in the enhancement-type LDMOSFET. That is, the enhancement-type LDMOSFET, which is not illustrated in the present specification, has the above-described p-type semiconductor region.

In this regard, in the depletion-type LDMOSFET formed in the region 1A, the p-type well PW1 is formed in the same step as the p-type well of the enhancement-type LDMOSFET. As a result, the impurity concentration of the p-type well PW1 is the same as an impurity concentration of the p-type well of the LDMOSFET. In addition, in the depletion-type LDMOSFET, a p-type semiconductor region having the same impurity concentration as that of the p-type semiconductor region of the LDMOSFET is formed in the upper surface region of the p-type well PW1 in the same step. However, in the depletion-type LDMOSFET, an n-type impurity is introduced into the upper surface region of the well so as to cancel out the p-type impurity constituting this p-type semiconductor region. As a result, in FIG. 1, instead of the p-type semiconductor region, the n-type semiconductor region 10A is formed in the upper surface region of the well. Accordingly, in the region 1A, the depletion-type LDMOSFET is realized by the n-type semiconductor region 10A.

FIG. 2 is a cross-sectional view illustrating a configuration formed in the region 1B of the semiconductor device 100.

In the region 1B, the low-Vth LDMOSFET is formed.

In FIG. 2, the semiconductor device 100 includes a p-type semiconductor substrate SUB, an n-type buried layer NBL, a p-type epitaxial layer EPI, a p-type RESURF layer HPW2, a p-type well PW2, an n-type well NW2, an n-type offset drain region OD2, an insulating region STI2, a drain region DR2, a source region SR2, a body contact region BC2, an n-type semiconductor region 10B, a gate insulating film GOX2, a gate electrode GE2, an interlayer insulating film IL, a plug PLG1B, a plug PLG2B, a source wiring WL1B, and a drain wiring WL2B.

In the p-type epitaxial layer EPI, the p-type RESURF layer HPW2, the p-type well PW2, the n-type well NW2, the n-type offset drain region OD2, the insulating region STI2, the drain region DR2, the source region SR2, the body contact region BC2, and the n-type semiconductor region 10B are formed. The n-type offset drain region OD2 is arranged apart from the p-type well PW2. Therefore, a portion located between the n-type offset drain region OD2 and the p-type well PW2 becomes a portion of the p-type epitaxial layer EPI.

An impurity concentration of the p-type RESURF layer HPW2 is higher than an impurity concentration of the p-type epitaxial layer EPI. Similarly, an impurity concentration of the p-type well PW2 is higher than the impurity concentration of the p-type epitaxial layer EPI. Also, an impurity concentration of the n-type offset drain region OD2 is lower than an impurity concentration of the n-type well NW2. The impurity concentration of the p-type RESURF layer HPW2 is the same as the impurity concentration of the p-type RESURF layer HPW1. Similarly, the impurity concentration of the p-type well PW2 is the same as the impurity concentration of the p-type well PW1. Also, the impurity concentration of the n-type offset drain region OD2 is the same as the impurity concentration of the n-type offset drain region OD1.

The insulating region STI2 is formed in the n-type offset drain region OD2 and in the n-type well NW2. The insulating region STI2 includes a trench formed on an upper surface of the p-type epitaxial layer EPI and an insulating film buried in the trench. The insulating region STI2 has a configuration similar to that of the insulating region STI1. The insulating region STI2 is located between the source region SR2 and the drain region DR2 in the X direction in FIG. 2.

In the n-type well NW2, the drain region DR2 is formed. The drain region DR2 is in contact with the insulating region STI2. The drain region DR2 is an n-type semiconductor region. An impurity concentration of the drain region DR2 is higher than the impurity concentration of the n-type well NW2. The impurity concentration of the drain region DR2 is the same as the impurity concentration of the drain region DR1.

In the p-type well PW2, the source region SR2 and the body contact region BC2 are formed. The source region SR2 and the body contact region BC2 are in contact with each other. The source region SR2 is an n-type semiconductor region. On the other hand, the body contact region BC2 is a p-type semiconductor region. An impurity concentration of the source region SR2 is higher than the impurity concentration of the n-type offset drain region OD2 and is approximately equal to the impurity concentration of the drain region DR2. An impurity concentration of the body contact region BC2 is higher than the impurity concentration of the p-type well PW2.

The impurity concentration of the source region SR2 is the same as the impurity concentration of the source region SR1. Also, the impurity concentration of the body contact region BC2 is the same as the impurity concentration of the body contact region BC1.

On an upper surface of the p-type well PW2, the n-type semiconductor region 10B is formed. Specifically, in the X direction of FIG. 2, a portion of the n-type offset drain region OD2, a p-type semiconductor region between the n-type offset drain region OD2 and the n-type semiconductor region 10B, and the n-type semiconductor region 10B are formed between the insulating region STI2 and the source region SR2. For example, the n-type semiconductor region 10B is in contact with a boundary between the p-type epitaxial layer EPI and the p-type well PW2 and is also in contact with the source region SR2.

In FIG. 2, the p-type semiconductor region between the n-type offset drain region OD2 and the n-type semiconductor region 10B is the p-type epitaxial layer EPI located between the n-type offset drain region OD2 and the p-type well PW2. That is, the n-type semiconductor region 10B is arranged apart from the n-type offset drain region OD2. For example, in FIG. 2, the n-type semiconductor region 10B reaches the boundary between the p-type epitaxial layer EPI and the p-type well PW2. However, the n-type semiconductor region 10B may not reach the boundary between the p-type epitaxial layer EPI and the p-type well PW2. In this case, the p-type semiconductor region between the n-type offset drain region OD2 and the n-type semiconductor region 10B includes a portion of the p-type epitaxial layer EPI located between the n-type offset drain region OD2 and the p-type well PW2 and a portion of the upper surface region of the p-type well PW2 located between the p-type epitaxial layer EPI and the n-type semiconductor region 10B.

On a portion of the insulating region STI2, on a portion of the n-type offset drain region OD2, on a portion of the p-type epitaxial layer EPI located between the n-type offset drain region OD2 and the p-type well PW2, on the n-type semiconductor region 10B, and on a portion of the source region SR2, the gate electrode GE2 is formed via the gate insulating film GOX2. Here, the X direction of FIG. 2 is a gate length direction of the gate electrode GE2.

On the drain region DR2, on a portion of the insulating region STI2, on the gate electrode GE2, on the source region SR2, and on the body contact region BC2, the interlayer insulating film IL is formed. In the interlayer insulating film IL, the plug PLG1B and the plug PLG2B penetrating the interlayer insulating film IL are formed. The plug PLG1B is connected to the source region SR2 and the body contact region BC2. Therefore, the source region SR2 and the body contact region BC2 are electrically connected to each other via the plug PLG1B. On the other hand, the plug PLG2B is connected to the drain region DR2.

On the interlayer insulating film IL, the source wiring WL1B and the drain wiring WL2B are formed. The source wiring WL1B is connected to the plug PLG1B. Therefore, the source wiring WL1B is electrically connected to the source region SR2 and the body contact region BC2 via the plug PLG1B. The drain wiring WL2B is connected to the plug PLG2B. Therefore, the drain wiring WL2B is electrically connected to the drain region DR2 via the plug PLG2B.

In the low-Vth LDMOSFET formed in the region 1B, the p-type well PW2 is formed in the same step as the p-type well of the enhancement-type LDMOSFET. As a result, the impurity concentration of the p-type well PW2 is the same as the impurity concentration of the p-type well of the LDMOSFET. Also, in the low-Vth LDMOSFET, the p-type semiconductor region having the same impurity concentration as that of the p-type semiconductor region of the LDMOSFET is also formed in the upper surface region of the p-type well PW2 in the same step. However, in the low-Vth LDMOSFET, an n-type impurity is introduced into the upper surface region of the well so as to cancel out the p-type impurity constituting this p-type semiconductor region. As a result, in FIG. 2, instead of the p-type semiconductor region, the n-type semiconductor region 10B is formed in the upper surface region of the well. Accordingly, in the region 1B, the low-Vth LDMOSFET is realized by the n-type semiconductor region 10B. Here, for example, when the n-type semiconductor region 10B does not reach the boundary between the p-type epitaxial layer EPI and the p-type well PW2, a p-type semiconductor region is formed in the upper surface region of the well located between the above boundary and the n-type semiconductor region 10B.

In the region 1A, the depletion-type LDMOSFET is realized by the n-type semiconductor region 10A illustrated in FIG. 1. In contrast, in the region 1B, the low-Vth LDMOSFET is realized by the n-type semiconductor region 10B illustrated in FIG. 2.

That is, as illustrated in FIG. 1, by forming the n-type semiconductor region 10A that reaches at least the n-type offset drain region OD1 and is in contact with the source region SR1, the depletion-type LDMOSFET is realized. On the other hand, as illustrated in FIG. 2, by forming the n-type semiconductor region 10B that is separated from the n-type offset drain region OD2 and is in contact with the source region SR2, the low-Vth LDMOSFET is realized.

For example, a length of the n-type semiconductor region 10A in the gate length direction of the gate electrode GE1 is greater than a length of the n-type semiconductor region 10B in the gate length direction of the gate electrode GE2. Accordingly, in the region 1A, the depletion-type LDMOSFET is realized, whereas in the region 1B, the low-Vth LDMOSFET is realized.

In the following, the description is made that, by forming the n-type semiconductor region 10B, the low-Vth LDMOSFET having a positive threshold voltage and also having a threshold voltage lower than that of the LDMOSFET can be realized.

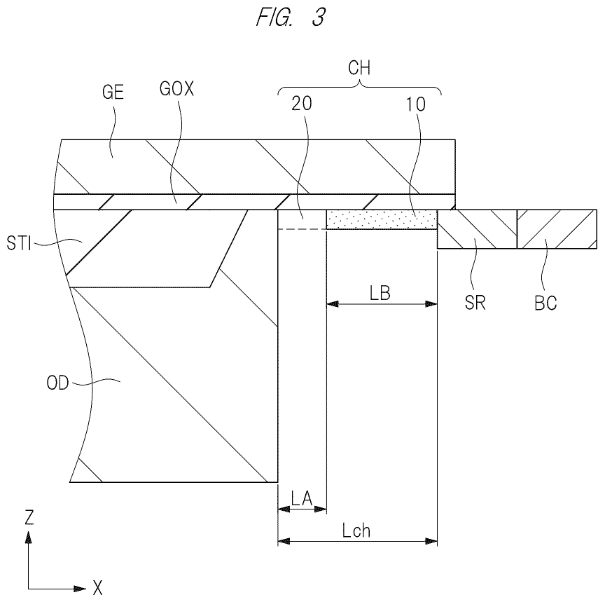

FIG. 3 is a diagram illustrating a configuration of a channel formation region CH located between an n-type offset drain region OD and a source region SR. In FIG. 3, the channel formation region CH is formed between the n-type offset drain region OD and the source region SR. A body contact region BC is formed so as to be in contact with the source region SR. An insulating region STI is formed so as to be in contact with the n-type offset drain region OD.

On the insulating region STI, on a portion of the n-type offset drain region OD, on the channel formation region CH, and on a portion of the source region SR, a gate electrode GE is formed via a gate insulating film GOX.

The channel formation region CH includes an n-type semiconductor region 10 and a p-type semiconductor region 20. A sum of a length LA of the p-type semiconductor region 20 in the X direction and a length LB of the n-type semiconductor region 10 in the X direction is a length Lch of the channel formation region CH in the X direction.

For example, when the length LA is 0, the channel formation region CH is constituted of the n-type semiconductor region 10. In this case, the configuration illustrated in FIG. 1 is realized, and the n-type semiconductor region 10 becomes the n-type semiconductor region 10A. As a result, in FIG. 3, when the length LA is 0, a depletion-type LDMOSFET having a negative threshold voltage is realized. In contrast, when the length LB is 0, the channel formation region CH is constituted of the p-type semiconductor region 20. In this case, an enhancement-type LDMOSFET having a positive threshold voltage is realized.

Therefore, for example, when the length LA is greater than 0 and the length LB is greater than 0 under a certain condition, it can be qualitatively understood that a low-Vth LDMOSFET having a positive threshold voltage and also having a threshold voltage lower than that of the above-described enhancement-type LDMOSFET can be realized. In the following, this point will be described in detail.

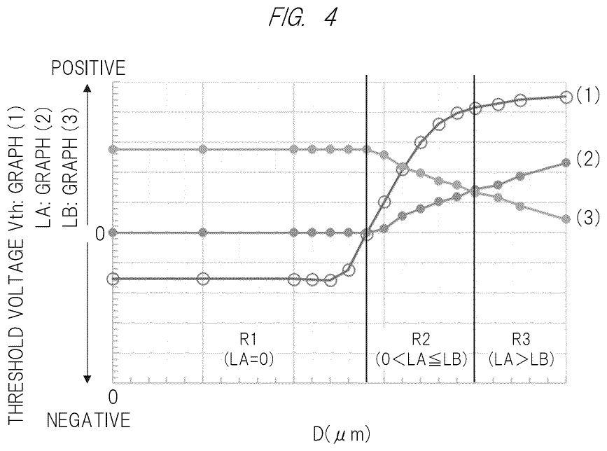

FIG. 4 illustrates a graph (1) illustrating a relationship between a position D of a mask edge and a threshold voltage Vth, a graph (2) illustrating a relationship between the position D of the mask edge and the length LA, and a graph (3) illustrating a relationship between the position D of the mask edge and the length LB.

A horizontal axis of FIG. 4 indicates the position D of the mask edge. A vertical axis of FIG. 4 indicates, in the graph (1), the threshold voltage Vth, in the graph (2), the length LA, and in the graph (3), the length LB. Here, referring to FIG. 3, the following qualitative finding can be obtained.

The mask is used for ion implantation to form the n-type semiconductor region 10. The horizontal axis of FIG. 4 indicates the position D of the mask edge from an edge of the insulating region STI in the X direction. When the mask edge is located on the edge of the insulating region STI, the position D of the mask edge is 0. Therefore, when D=0, the n-type semiconductor region 10 in contact with both the insulating region STI and the source region SR is formed. As a result, a depletion-type LDMOSFET having a negative threshold voltage is realized.

When the position D is increased to be greater than 0, until the position D reaches an edge of the n-type offset drain region OD, the length Lch becomes the same as the length LB, therefore, the depletion-type LDMOSFET is obtained. When the position D becomes greater than the position of the edge of the n-type offset drain region OD from the insulating region STI, the length LA becomes greater than 0, and the p-type semiconductor region 20 is formed in the channel formation region CH. As a result, the threshold voltage gradually increases due to the p-type semiconductor region 20. Thereafter, as the position D increases, the length of the p-type semiconductor region 20 in the X direction becomes longer, and as a result, the threshold voltage increases further and changes from the negative threshold voltage to the positive threshold voltage. For example, when the position D further increases, the length of the p-type semiconductor region 20 in the X direction becomes further longer, and consequently, the threshold voltage increases further and finally saturates.

Based on this finding, referring to the graph (1) of FIG. 4, the above-described finding can explain a behavior of the graph (1). In FIG. 4, based on the graph (2) and the graph (3), FIG. 4 has the following three regions. A region R1 indicates a state in which the length LA is 0. In the region R1, since the p-type semiconductor region 20 is not present, the region R1 is a region where the depletion-type LDMOSFET having a negative threshold voltage is realized. A region R3 indicates a state in which the length LA is greater than the length LB. In the region R3, referring to the graph (1) of FIG. 4, since the positive threshold voltage is substantially saturated, the region R3 is a region where the enhancement-type LDMOSFET having the positive threshold voltage is realized. In contrast, a region R2 indicates a state in which the length LA is greater than 0 and equal to or less than the length LB. In the region R2, referring to the graph (1) of FIG. 4, the positive threshold voltage gradually increases. Accordingly, in the region R2, the low-Vth LDMOSFET having the positive threshold voltage and also having a threshold voltage lower than that of the enhancement-type LDMOSFET is realized.

Therefore, by satisfying a condition within a range of the region R2, the low-Vth LDMOSFET can be realized. That is, when the length LA of a portion located between the n-type offset drain region OD and the n-type semiconductor region 10 in the gate length direction (X direction) of the gate electrode GE is equal to or less than the length LB of the n-type semiconductor region 10 in the gate length direction of the gate electrode GE, the low-Vth LDMOSFET can be realized. In other words, when the length LA of the p-type semiconductor region 20 in the gate length direction (X direction) of the gate electrode GE is equal to or less than the length LB of the n-type semiconductor region 10 in the gate length direction of the gate electrode GE, the low-Vth LDMOSFET can be realized.

### <<Structural Feature of Semiconductor Device>>

For example, a channel formation region of the enhancement-type LDMOSFET is constituted of a p-type semiconductor region. A channel formation region of the low-Vth LDMOSFET having a positive threshold voltage and also having a threshold voltage lower than that of the above-described LDMOSFET is also generally constituted of a p-type semiconductor region. At this point, an impurity concentration of the p-type semiconductor region of the low-Vth LDMOSFET having the lower threshold voltage is different from an impurity concentration of the p-type semiconductor region of the above-described LDMOSFET. Accordingly, the low-Vth LDMOSFET is realized. Also, a channel formation region of the depletion-type LDMOSFET is constituted of an n-type semiconductor region.

Therefore, in order to manufacture the semiconductor device including not only the LDMOSFET but also the low-Vth LDMOSFET and the depletion-type LDMOSFET, it is necessary to additionally provide a step of forming the n-type semiconductor region of the depletion-type LDMOSFET and a step of forming the p-type semiconductor region of the low-Vth LDMOSFET having an impurity concentration different from that of the p-type semiconductor region of the LDMOSFET. In this case, the manufacturing cost of the semiconductor device increases.

Accordingly, the embodiment has the following feature. That is, the channel formation region of the low-Vth LDMOSFET includes the p-type semiconductor region having the same impurity concentration as that of the p-type semiconductor region of the enhancement-type LDMOSFET and the n-type semiconductor region having the same impurity concentration as that of the n-type semiconductor region of the depletion-type LDMOSFET. Then, the p-type semiconductor region and the n-type semiconductor region are formed so as to satisfy the condition within the range of the region R2 of FIG. 4 described above. Accordingly, according to the embodiment, the low-Vth LDMOSFET can be realized.

In the following, the description will be made that, by adopting the low-Vth LDMOSFET having such a structure, the manufacturing process of the semiconductor device including not only the LDMOSFET but also the low-Vth LDMOSFET and the depletion-type LDMOSFET can be simplified.

### <<Method of Manufacturing Semiconductor Device>>

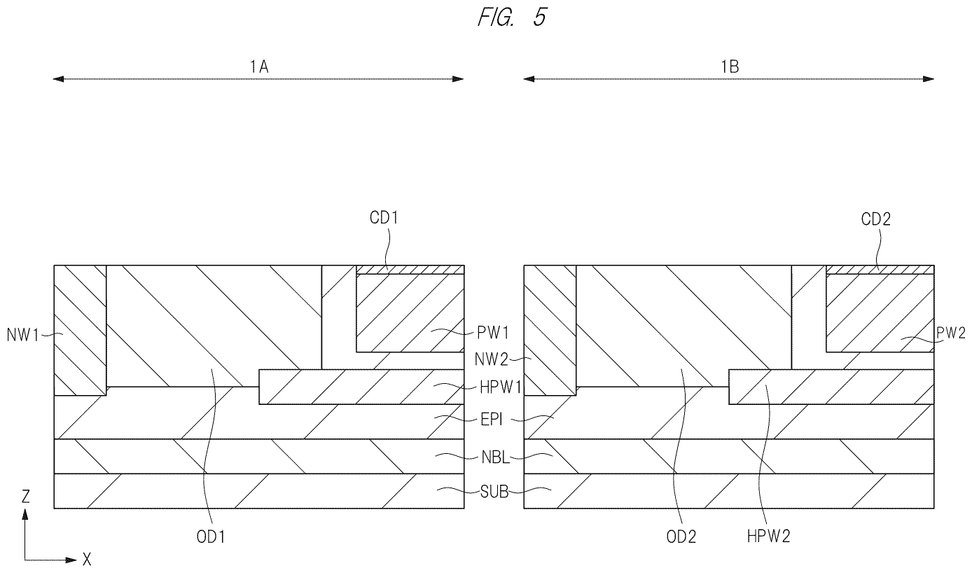

As illustrated in FIG. 5, by using an ion implantation method, an n-type impurity is introduced into the p-type semiconductor substrate SUB. Accordingly, an n-type buried layer NBL is formed in the p-type semiconductor substrate SUB. Next, for example, by using an epitaxial growth method, a p-type epitaxial layer EPI is formed on the p-type semiconductor substrate SUB in which the n-type buried layer NBL is formed.

Subsequently, by using a photolithography technique and the ion implantation method, a p-type impurity is introduced into the p-type epitaxial layer EPI formed in the region 1A and into the p-type epitaxial layer EPI formed in the region 1B. Accordingly, in the p-type epitaxial layer EPI in the region 1A, a p-type RESURF layer HPW1, a p-type well PW1, and a p-type semiconductor region CD1 are formed. In the p-type epitaxial layer EPI in the region 1B, a p-type RESURF layer HPW2, a p-type well PW2, and a p-type semiconductor region CD2 are formed.

In a p-type epitaxial layer EPI formed in a formation region of an enhancement-type LDMOSFET which is not illustrated, a p-type impurity is also introduced. Accordingly, in the p-type epitaxial layer EPI formed in the formation region of the enhancement-type LDMOSFET which is not illustrated, a p-type RESURF layer, a p-type well, and a p-type semiconductor region are formed.

The p-type semiconductor region is formed in the enhancement-type LDMOSFET in order to realize a positive threshold voltage. Here, the p-type well, the p-type well PW1, and the p-type well PW2 are formed in the same ion implantation step using a mask opening each of a formation region of the p-type well, a formation region of the p-type well PW1, and a formation region of the p-type well PW2. Then, since the p-type semiconductor region is formed in an upper surface region of the p-type well using this mask, the p-type semiconductor region CD1 is inevitably formed in an upper surface region of the p-type well PW1, and the p-type semiconductor region CD2 is inevitably formed in an upper surface region of the p-type well PW2.

An impurity concentration of the p-type RESURF layer HPW1, an impurity concentration of the p-type RESURF layer HPW2, and an impurity concentration of the p-type RESURF layer are the same. An impurity concentration of the p-type well PW1, an impurity concentration of the p-type well PW2, and an impurity concentration of the p-type well are the same. An impurity concentration of the p-type semiconductor region CD1, an impurity concentration of the p-type semiconductor region CD2, and an impurity concentration of the p-type semiconductor region are the same.

Next, by using a photolithography technique and the ion implantation method, an n-type impurity is introduced into the p-type epitaxial layer EPI formed in the region 1A and into the p-type epitaxial layer EPI formed in the region 1B. Accordingly, in the p-type epitaxial layer EPI in the region 1A, an n-type well NW1 and an n-type offset drain region OD1 are formed. In the p-type epitaxial layer EPI in the region 1B, an n-type well NW2 and an n-type offset drain region OD2 are formed. The n-type offset drain region OD1 is formed at a position spaced apart from the p-type well PW1. The n-type offset drain region OD2 is formed at a position spaced apart from the p-type well PW2.

In the p-type epitaxial layer EPI formed in the formation region of the enhancement-type LDMOSFET which is not illustrated, an n-type impurity is also introduced. Accordingly, in the p-type epitaxial layer EPI formed in the formation region of the enhancement-type LDMOSFET which is not illustrated, an n-type well and an n-type offset drain region are formed. The n-type offset drain region is formed at a position spaced apart from the p-type well.

An impurity concentration of the n-type well NW1, an impurity concentration of the n-type well NW2, and an impurity concentration of the n-type well are the same. An impurity concentration of the n-type offset drain region OD1, an impurity concentration of the n-type offset drain region OD2, and an impurity concentration of the n-type offset drain region are the same. In the following description of the steps, a formation region of the enhancement-type LDMOSFET which is not illustrated is not referred to, but may be referred to as necessary.

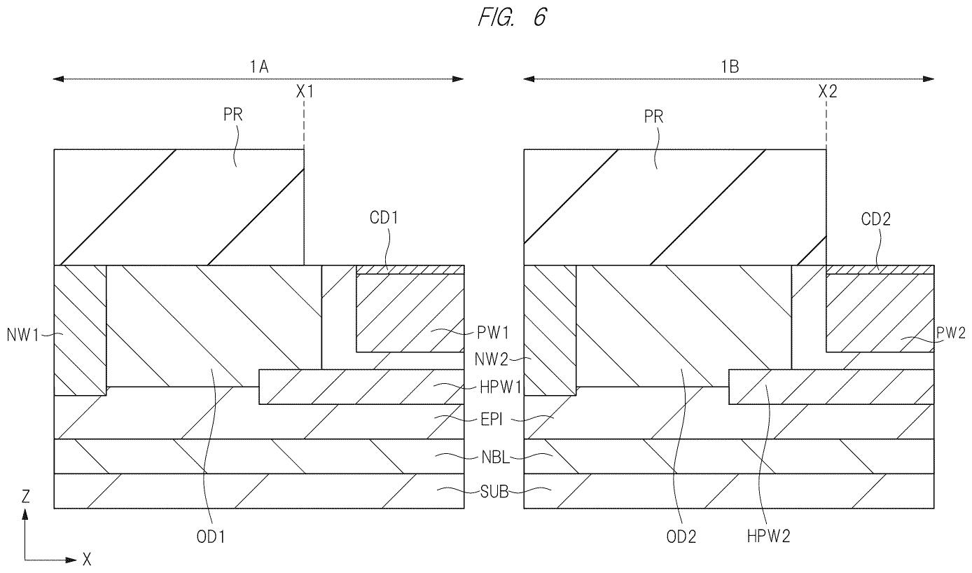

Next, as illustrated in FIG. 6, after a resist film PR is formed above the p-type epitaxial layer EPI, by using a photolithography technique, the resist film PR is patterned to form a mask. The patterning of the resist film PR is performed such that an edge of the resist film PR is located at “X1” in the region 1A, and an edge of the resist film PR is located at “X2” in the region 1B. The “X1” and the “X2” are not limited to the positions illustrated in FIG. 6. That is, in the region 1B, a mask that covers the n-type offset drain region OD2, a portion which is in contact with the n-type offset drain region OD2, of the p-type epitaxial layer EPI, and, in the region 1A, a portion of the n-type offset drain OD1, while exposes, at least a portion of the p-type well PW2, an other portion of the n-type offset drain region OD1 a portion, which is located between the n-type offset drain region OD1 and the p-type well PW1, of the p-type epitaxial layer EPI, and the p-type well PW1, is formed on the p-type epitaxial layer EPI. Here, in the region 1B of FIG. 6, a state in which the entire p-type well PW2 is exposed from the resist film PR is illustrated as an example, but a state in which a portion of the p-type well PW2 is exposed and another portion of the p-type well PW2 is covered with the resist film PR may also be adopted.

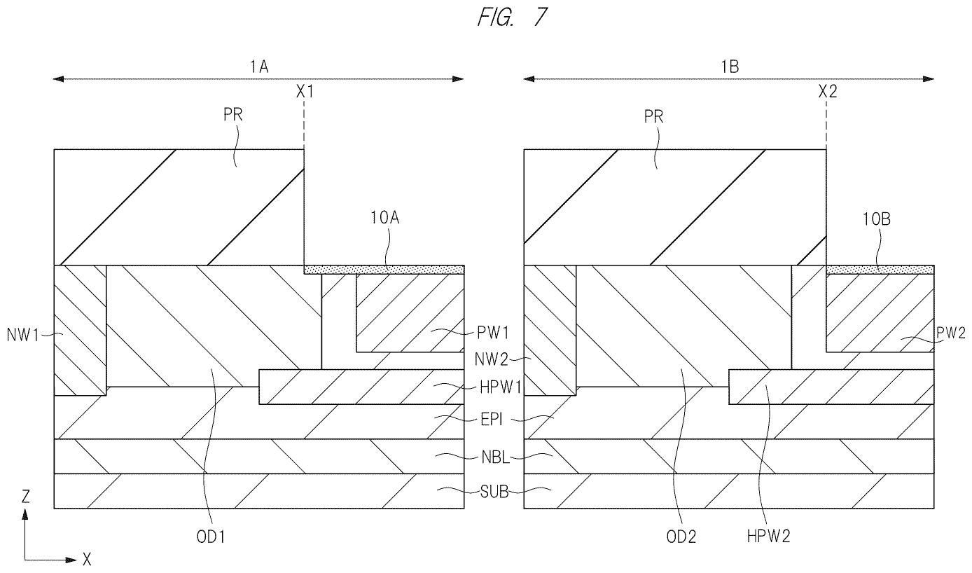

Subsequently, as illustrated in FIG. 7, by using an ion implantation method, an n-type impurity is introduced into the p-type epitaxial layer EPI in a state in which the mask formed of the patterned resist film PR is formed. Accordingly, in the region 1B, an n-type semiconductor region 10B is formed in the p-type well PW2, and in the region 1A, an n-type semiconductor region 10A is formed in each of in the p-type well PW1, the portion, which is located between the n-type offset drain region OD1 and the p-type well lPW1, of the p-type epitaxial layer EPI.

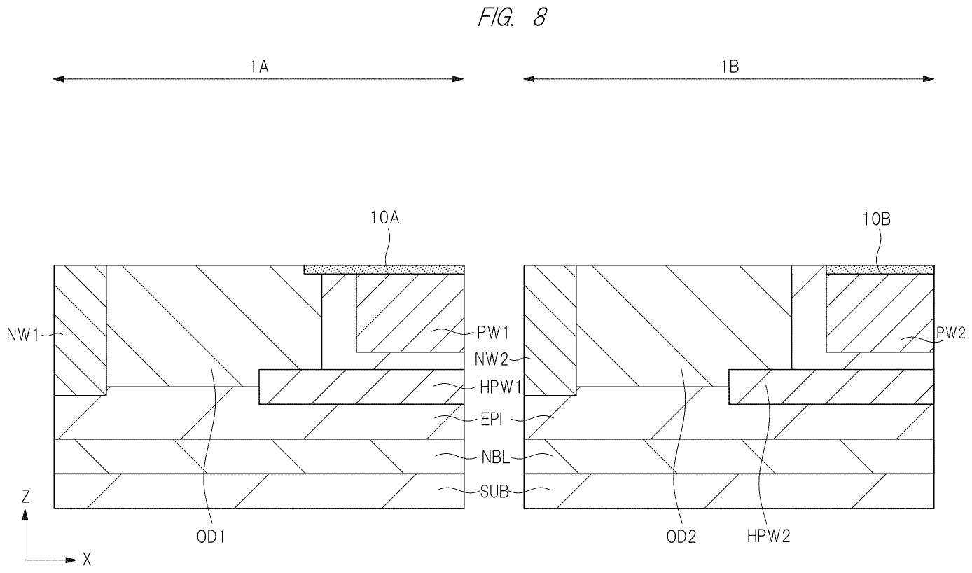

Thereafter, as illustrated in FIG. 8, by using an ashing technique, the mask formed of the patterned resist film PR is removed.

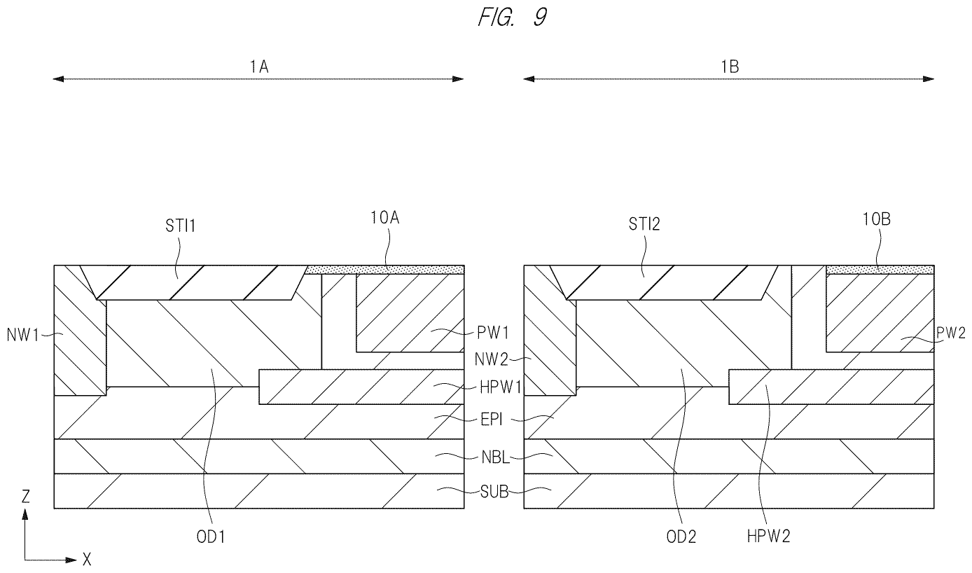

Next, as illustrated in FIG. 9, in the region 1A, an insulating region STI1 is formed in the n-type well NW1 and in the n-type offset drain region OD1, and in the region 1B, an insulating region STI2 is formed in the n-type well NW2 and in the n-type offset drain region OD2.

For example, a step of forming the insulating region STI1 includes a step of forming a trench in the n-type well NW1 and in the n-type offset drain region OD1, and a step of burying an insulating film in the trench. In addition, a step of forming the insulating region STI2 includes a step of forming a trench in the n-type well NW2 and in the n-type offset drain region OD2, and a step of burying an insulating film in the trench.

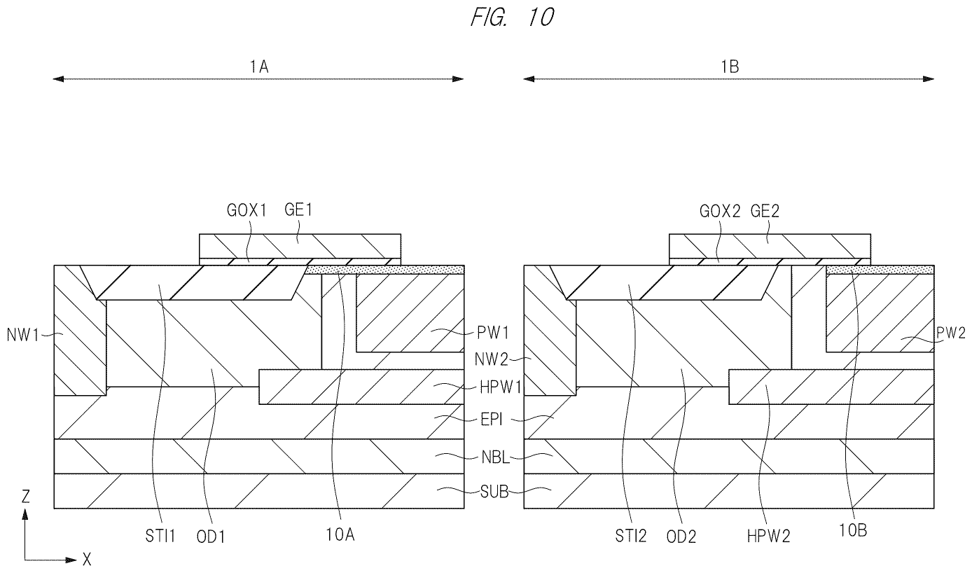

Subsequently, as illustrated in FIG. 10, in the region 1A, a gate electrode GE1 is formed via a gate insulating film GOX1 on a portion of the insulating region STI1 and on a portion of the n-type semiconductor region 10A. In addition, in the region 1B, a gate electrode GE2 is formed via a gate insulating film GOX2 on the insulating region STI2, on a portion of the n-type offset drain region OD2, on a portion of the p-type epitaxial layer EPI located between the n-type offset drain region OD2 and the n-type semiconductor region 10B, and on a portion of the n-type semiconductor region 10B.

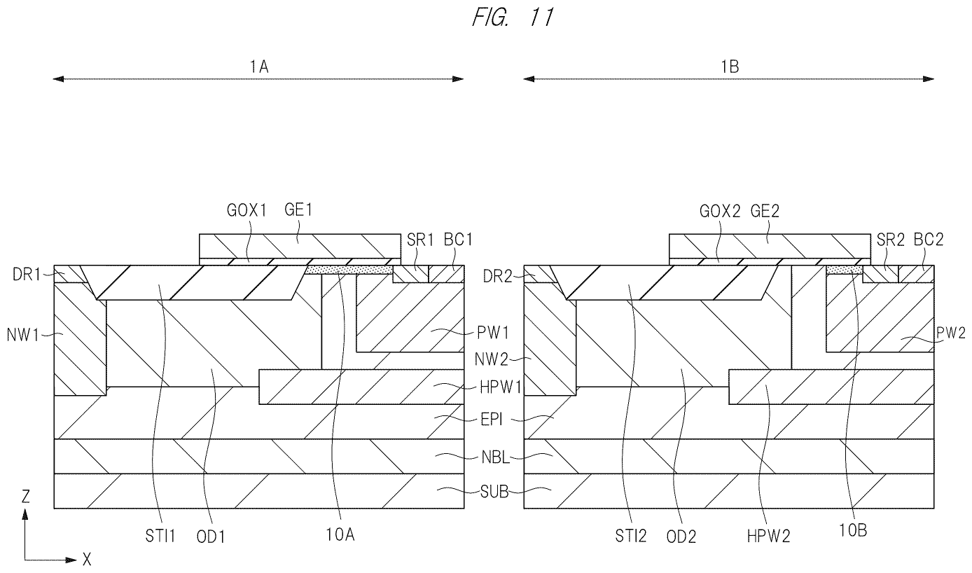

Thereafter, as illustrated in FIG. 11, by using a photolithography technique and the ion implantation method, in the region 1A, a source region SR1 is formed in the p-type well PW1, and a drain region DR1 is formed in the n-type well NW1. The source region SR1 has an impurity concentration higher than that of the n-type semiconductor region 10A. The drain region DR1 has an impurity concentration higher than that of the n-type well NW1. Also, in the region 1B, a source region SR2 is formed in the p-type well PW2, and a drain region DR2 is formed in the n-type well NW2. The source region SR2 has an impurity concentration higher than that of the n-type semiconductor region 10B. The drain region DR2 has an impurity concentration higher than that of the n-type well NW2.

Further, by using a photolithography technique and the ion implantation method, in the region 1A, a body contact region BC1 is formed in the p-type well PW1, and in the region 1B, a body contact region BC2 is formed in the p-type well PW2. The body contact region BC1 has an impurity concentration higher than that of the p-type well PW1. The body contact region BC2 has an impurity concentration higher than that of the p-type well PW2.

As illustrated in FIG. 11, the n-type semiconductor region 10A is in contact with the source region SR1 and is in contact with the insulating region STI1. In contrast, the n-type semiconductor region 10B is in contact with the source region SR2 but is separated from the n-type offset drain region OD2.

At this time, a length of a portion located between the n-type offset drain region OD2 and the n-type semiconductor region 10B in a gate length direction (X direction) of the gate electrode GE2 is equal to or less than a length of the n-type semiconductor region 10B in the gate length direction of the gate electrode GE2.

In addition, a length of the n-type semiconductor region 10A in the gate length direction of the gate electrode GE1 is greater than a length of the n-type semiconductor region 10B in the gate length direction of the gate electrode GE2.

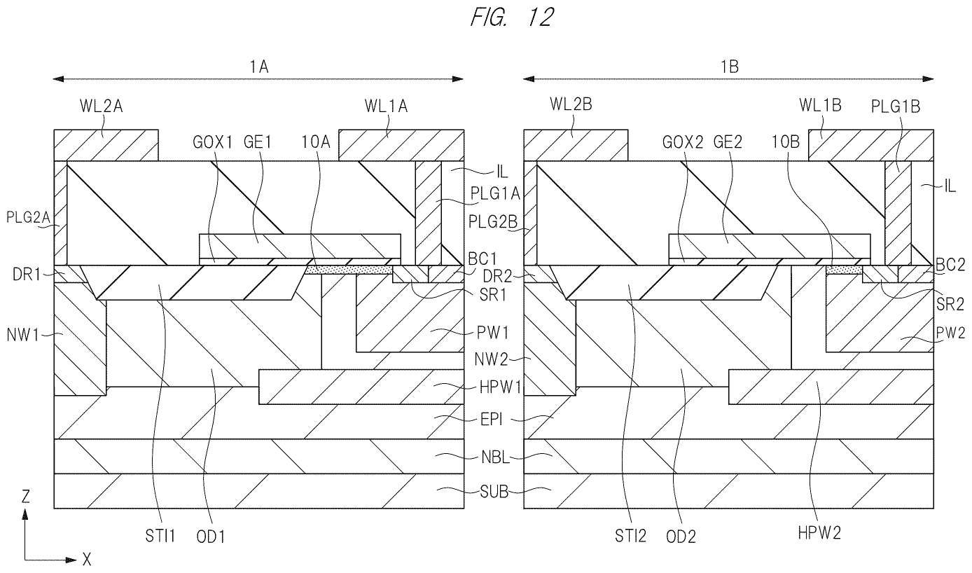

Next, as illustrated in FIG. 12, in the region 1A, an interlayer insulating film IL is formed on the drain region DR1, on a portion of the insulating region STI1, on the gate electrode GE1, on the source region SR1, and on the body contact region BC1, and in the region 1B, an interlayer insulating film IL is formed on the drain region DR2, on a portion of the insulating region STI2, on the gate electrode GE2, on the source region SR2, and on the body contact region BC2.

Then, in the region 1A, a plug PLG1A and a plug PLG2A penetrating the interlayer insulating film IL are formed. The plug PLG1A is connected to the source region SR1 and the body contact region BC1. The plug PLG2A is connected to the drain region DR1.

In the region 1B, a plug PLG1B and a plug PLG2B penetrating the interlayer insulating film IL are formed. The plug PLG1B is connected to the source region SR2 and the body contact region BC2. The plug PLG2B is connected to the drain region DR2.

Thereafter, in the region 1A, a source wiring WL1A and a drain wiring WL2A are formed on the interlayer insulating film IL. The source wiring WL1A is connected to the plug PLG1A. The drain wiring WL2A is connected to the plug PLG2A.

In the region 1B, a source wiring WL1B and a drain wiring WL2B are formed on the interlayer insulating film IL. The source wiring WL1B is connected to the plug PLG1B. The drain wiring WL2B is connected to the plug PLG2B.

As described above, the semiconductor device including the low-Vth LDMOSFET and the depletion-type LDMOSFET can be manufactured.

### <<Features of Method of Manufacturing Semiconductor Device>>

According to the embodiment, in the LDMOSFET, the low-Vth LDMOSFET, and the depletion-type LDMOSFET, the wells can be formed in the same ion implantation step, and the upper surface regions of the wells (p-type semiconductor regions) can also be formed in the same ion implantation step. Therefore, according to the embodiment, it is not necessary to additionally provide the ion implantation step for forming the well and the upper surface region of the well specific to the low-Vth LDMOSFET (first feature).

As illustrated in FIG. 7, the n-type semiconductor region 10B of the low-Vth LDMOSFET can be formed in the same ion implantation step as the n-type semiconductor region 10A of the depletion-type LDMOSFET. Here, the layout of the n-type semiconductor region 10B of the low-Vth LDMOSFET and the layout of the n-type semiconductor region 10A of the depletion-type LDMOSFET can be changed by a mask (the patterned resist film PR) used in the same ion implantation step (second feature).

From the above, according to the embodiment, by adopting the structure illustrated in FIG. 2 as the structure of the low-Vth LDMOSFET, the manufacturing process of the semiconductor device including not only the LDMOSFET but also the low-Vth LDMOSFET and the depletion-type LDMOSFET can be simplified. As a result, according to the embodiment, the manufacturing cost of the semiconductor device can be reduced.

In the foregoing, the invention made by the inventor has been concretely described on the basis of the embodiment. However, it is needless to say that the present invention is not limited to the foregoing embodiment, and various modifications and alterations can be made within the scope of the present invention.

What is claimed is:

1. A semiconductor device comprising:
an epitaxial layer of a first conductivity type;
a first well formed in the epitaxial layer, the first well being of the first conductivity type;
a first offset drain region formed in the epitaxial layer and arranged apart from the first well, the first offset drain region being of a second conductivity type;
a first source region formed in the first well, the first source region being of the second conductivity type;
a first semiconductor region formed in the first well, in contact with the first source region, arranged apart from the first offset drain region, and having an impurity concentration lower than an impurity concentration of the first source region, the first semiconductor region being of the second conductivity type; and
a first gate electrode formed on each of: a portion of the first offset drain region; a portion, which is located between the first offset drain region and the first semiconductor region, of the epitaxial layer; and the first semiconductor region, via a first gate insulating film,
wherein, in a gate length direction of the first gate electrode, a length of the portion, which is located between the first offset drain region and the first semiconductor region, of the epitaxial layer is equal to or less than a length of the first semiconductor region.

2. The semiconductor device according to claim 1,
wherein the semiconductor device includes
a first trench formed in the first offset drain region,
a first insulating film buried in the first trench, and
a first drain region of the second conductivity type in contact with the first trench and having an impurity concentration higher than that of the first offset drain region, and
wherein the first trench is located between the first source region and the first drain region.

3. The semiconductor device according to claim 1,
wherein the first conductivity type is a p-type, and
wherein the second conductivity type is an n-type.

4. The semiconductor device according to claim 1,
wherein the epitaxial layer includes a first portion and a second portion,
wherein the first gate electrode is formed on the first portion via the first gate insulating film,
wherein the first well is formed in the first portion,
wherein the first offset drain region is formed in the first portion,
wherein the first source region is formed in the first portion,
wherein the first semiconductor region is formed in the first portion, and
wherein the semiconductor device includes
a second well of the first conductivity type formed in the second portion,
a second offset drain region of the second conductivity type formed in the second portion and arranged apart from the second well,
a second source region of the second conductivity type formed in the second well,
a second semiconductor region of the second conductivity type formed in the second well, in contact with the second source region, in contact with the second offset drain region, and having a lower impurity concentration than that of the second source region,
a second gate insulating film formed on at least the second semiconductor region, and
a second gate electrode formed on the second gate insulating film.

5. The semiconductor device according to claim 4,
wherein a length of the second semiconductor region in a gate length direction of the second gate electrode is greater than a length of the first semiconductor region in the gate length direction of the first gate electrode.

6. The semiconductor device according to claim 4,
wherein the second semiconductor region is also formed in a portion of the second offset drain region.

7. The semiconductor device according to claim 4,
wherein the semiconductor device includes
a first trench formed in the first offset drain region,
a first insulating film buried in the first trench,
a first drain region of the second conductivity type in contact with the first trench and having an impurity concentration higher than that of the first offset drain region,
a second trench formed in the second offset drain region,
a second insulating film buried in the second trench, and
a second drain region of the second conductivity type in contact with the second trench and having an impurity concentration higher than that of the second offset drain region,
wherein the first trench is located between the first source region and the first drain region,
wherein the second trench is located between the second source region and the second drain region, and
wherein the second semiconductor region is in contact with the second trench.

8. The semiconductor device according to claim 4,
wherein the first conductivity type is a p-type, and
wherein the second conductivity type is an n-type.

9. A method of manufacturing a semiconductor device comprising steps of:
(a) forming an epitaxial layer of a first conductivity type, the epitaxial layer having a first portion and a second portion;
(b) by implanting an impurity into the epitaxial layer, forming a first well in the first portion, and forming a second well in the second portion, each of the first well and the second well being of the first conductivity type;
(c) forming a first offset drain region in the first portion at a position spaced apart from the first well, the first offset drain region being of a second conductivity type;
(d) forming a second offset drain region in the second portion at a position spaced apart from the second well, the second offset drain region being of the second conductivity type;
(e) forming a mask covering: the first offset drain region; a portion, which is in contact with the first offset drain region, of the first portion of the epitaxial layer; and a portion of the second offset drain region, while exposing: at least a portion of the first well; an other portion of the second offset drain region; a portion, which is located between the second offset drain region and the second well, of the epitaxial layer; and the second well, on the epitaxial layer; and
(f) by introducing an impurity of the second conductivity type into the epitaxial layer in a state in which the mask is formed, forming a first semiconductor region in the first well, and forming a second semiconductor region in each of the second well and the portion, which is located between the second offset drain region and the second well, of the epitaxial layer.

10. The method of manufacturing the semiconductor device according to claim 9, further comprising steps of:
(g) forming a first trench in the first offset drain region;
(h) forming a second trench in the second offset drain region;
(i) burying a first insulating film in the first trench; and
(j) burying a second insulating film in the second trench.

11. The method of manufacturing the semiconductor device according to claim 10, further comprising steps of:
(k) forming a first gate electrode via a first gate insulating film on a portion of the first offset drain region, on a portion of the epitaxial layer located between the first offset drain region and the first semiconductor region, and on the first semiconductor region;
(l) forming a second gate electrode via a second gate insulating film on a portion of the second offset drain region and on the second semiconductor region;
(m) forming, in the first well, a first source region of the second conductivity type having an impurity concentration higher than that of the first semiconductor region; and
(n) forming, in the second well, a second source region of the second conductivity type having an impurity concentration higher than that of the second semiconductor region,
wherein the first semiconductor region is in contact with the first source region but is separated from the first offset drain region,
wherein the second semiconductor region is in contact with the second source region and is in contact with the second trench, and
wherein a length of a portion located between the first offset drain region and the first semiconductor region in a gate length direction of the first gate electrode is equal to or less than a length of the first semiconductor region in the gate length direction of the first gate electrode.

12. The method of manufacturing the semiconductor device according to claim 11,
wherein a length of the second semiconductor region in a gate length direction of the second gate electrode is greater than a length of the first semiconductor region in the gate length direction of the first gate electrode.

13. The method of manufacturing the semiconductor device according to claim 9,
wherein the first conductivity type is a p-type, and
wherein the second conductivity type is an n-type.
